(19) United States
(12) Patent Application Publication
(10) Pub. No.: US 2004/0154658 A1
(43) Pub. Date: Aug. 12, 2004

(54) Solar cell and fabrication method thereof, interconnector for solar cell, solar cell string, and solar cell module

(75) Inventors: Satoshi Tanaka, Yamatotakada-shi (JP); Masaomi Hioki, Gose-shi (JP)

Correspondence Address: NIXON & VANDERHYE, PC, 1100 N GLEBE ROAD, 8TH FLOOR, ARLINGTON, VA, 22201-4714, US

(73) Assignee: SHARP KABUSHIKI KAISHA, Osaka (JP)

(21) Appl. No.: 10/673,367

(22) Filed: Sep. 30, 2003

(30) Foreign Application Priority Data
Oct. 22, 2002 (JP) 2002-307522(P)

(51) Int. Cl. H01L 31/00

(52) U.S. Cl. 136/256; 438/98

(57) ABSTRACT

A solar cell has phosphorus included in a lead-free solder layer that covers silver electrodes. The amount of phosphorus in the lead-free solder is preferably 0.00001 to 0.5 mass %. The silver electrodes are silver paste electrodes formed by firing silver paste. A solar cell string interconnects such solar cells with an interconnector coated with the lead-free solder. A solar cell module incorporates such a string. Thus, a solar cell of high reliability, improved in wettability of lead-free solder, exhibiting thin coating of an electrode by lead-free solder, suppressed in detachment of interconnector a solar cell string, or a solar cell module can be provided.

### BACKGROUND OF THE INVENTION

1. Field of the Invention

The present invention relates to a solar cell, particularly a solar cell having an electrode coated with lead-free solder, a fabrication method of such a solar cell, an interconnector for such solar cells, a solar cell string, and a solar cell module.

2. Description of the Related Art

A schematic sectional view of a conventional solar cell in a solder coating process is shown in FIG. 4. An n type diffusion layer 2 is formed at one side, identified as the light receiving side, of a p type silicon substrate 1 subjected to etching. A major part of the region of n type diffusion layer 2 is covered with an anti-reflection film 3 directed to reduce the surface reflectance. Also, a back surface aluminum electrode 4 is formed covering the major region at the back side of p type silicon substrate 1. Silver electrodes 5 and 6 are formed at a partial region at the light receiving side of n type diffusion layer 2 and a partial region at the back side of p type silicon substrate 1, respectively. Each of silver electrodes 5 and 6 is coated with a solder layer 8.

Such a solar cell is fabricated by the processing steps shown in FIG. 3. Specifically, in the case where crystalline silicon is employed, p type silicon substrate 1 is first subjected to etching. Following this substrate etching step, an n type diffusion layer formation step is conducted to form an n type diffusion layer 2 at the light receiving side of p type silicon substrate 1 subjected to etching. Then, an anti-reflection film formation step of forming an anti-reflection film 3 directed to reduce the surface reflectance is conducted.

The back surface of p type silicon substrate 1 is subjected to screen-printing, whereby substantially the entire surface (excluding the region where a silver electrode is to be formed at the back surface at a subsequent step) is printed with aluminum paste. The aluminum paste is dried and fired in an oxidizing atmosphere at high temperature to form a back surface aluminum electrode 4. This processing stage corresponds to the back surface aluminum paste printing, drying, and firing step.

Also, a partial region of the light receiving side of anti-reflection film 3 and a partial region at the back side of p type silicon substrate 1 have a pattern of silver paste printed through screen-printing. The silver paste is fired in an oxidizing atmosphere at high temperature to form respective silver electrodes 5 and 6. Specifically, a back surface silver paste printing and drying step is conducted, followed by firing to form silver electrode 6. Also, a light receiving side silver paste printing and drying step is conducted, followed by firing to form silver electrode 5. At this stage, the printed and dried silver paste on anti-reflection film 3 at the light receiving side has the silver paste constituent transmitted through anti-reflection film 3 so as to reach as far as n type diffusion layer 2 by the firing process. Therefore, silver electrode 5 will be formed on n type diffusion layer 2, as shown in FIG. 4. In the case where silver electrode 5 and silver electrode 6 are to be formed at the same time, a simultaneous firing step of firing the printed and dried silver paste at both the light receiving side and back side at the same, time is allowed.

Then, the solar cell device formed as described above is immersed in an activator-containing flux at normal temperature for several ten seconds. Following this flux immersing step, the solar cell device is exposed to hot air to be dried. Then, the solar cell device is immersed in a 6:4 eutectic solder bath containing 2 mass % silver at approximately 195° C. for approximately one minute to have a coat of solder layer 8 applied on silver electrodes 5 and 6.

Following this coating step of solder layer 8, the solar cell device is ultrasonically washed several times in water of ordinary temperature or hot water, then rinsed with pure water, and exposed to hot air to be dried. Thus, a solar cell is fabricated through the above-described steps.

A solar cell is interconnected with an interconnector to form a string, as shown in FIG. 5. Specifically, referring to the conventional string of FIG. 5, a surface main electrode 21 of a solar cell 10 is coated with 6:4 eutectic solder. A plurality of solar cells 10 are connected by an interconnector 22 coated with 6:4 eutectic solder. Such a string was fabricated as set forth below. Interconnector 22 identified as a copper core line coated with 6:4 eutectic solder is superimposed on main electrode 21 coated with 6:4 eutectic solder of solar cell 10, and then exposed to a blow of hot air at approximately 400° C. to melt the solder. The solder is then cooled to be solidified to establish attachment. This process is repeated for the plurality of solar cells on the front and back sides to produce a solar cell string. The string is used to fabricate a solar cell module.

From the standpoint of environmental apprehension nowadays, the ill effect of lead to the human body is of great concern. The trend is towards developing various devices absent of lead. The demand for fabricating a solar cell in a lead-free state, i.e., not containing lead, is great.

To meet such demands, a solar cell is proposed, having the silver electrode coated with Sn—Bi—Ag based or Sn—Ag based lead-free solder (refer to Japanese Patent Laying-Open No. 2002-217434).

However, the wettability of the aforementioned lead-free solder is lower than that of the conventional 6:4 eutectic solder, and the solder thickness of the electrode coated with such lead-free solder will be increased. There is the possibility of degradation in adherence between the solar cell and the silver electrode to which the interconnector is attached as well as the disadvantage of degradation in appearance.

### SUMMARY OF THE INVENTION

In view of the foregoing, an object of the present invention is to provide a solar cell of high reliability, improved in the wettability of lead-free solder, exhibiting thin coating of an electrode by lead-free solder, and having detachment of an interconnector suppressed, and a fabrication method of such a solar cell.

Another object of the present invention is to provide an interconnector coated with such lead-free solder.

A further object of the present invention is to provide a solar cell string and module of high reliability, having such solar cells interconnected with such an interconnector.

According to an aspect of the present invention, a solar cell has an electrode coated with lead-free solder, characterized in that the lead-free solder includes phosphorous (P). In the present invention, the amount of phosphorous (P) contained in the lead-free solder is preferably 0.00001 to 0.5 mass %. Also, the lead-free solder is preferably Sn—Bi—Ag based solder.

The electrode of the solar cell of the present invention is preferably a silver electrode formed by firing silver paste. Also preferably, the average grain size of powdery glass included in the silver paste is 11 μm at most, the amount of powdery glass contained in the silver paste is 2.8 to 10.0 mass %, or the average thickness of the silver electrode is at least 15 μm.

According to a further aspect of the present invention, a fabrication method of a solar cell including the steps of printing silver paste at a partial region at a light receiving side of an anti-reflection film and at a partial region at a back side of a p type silicon substrate, firing the silver paste to form a silver electrode, and coating the silver electrode with lead-free solder containing phosphorous is characterized in that powdery glass included in the silver paste is sifted through a sieve having an opening diameter of 73 μm at most, the silver paste is applied at least two times by printing in the silver paste printing step, or a mask having a thickness of three times the wire diameter is used in printing the silver paste.

According to yet another aspect of the present invention, an interconnector for a solar cell is coated with the lead-free solder including phosphorus.

According to yet a still further aspect of the present invention, a solar cell string interconnects a solar cell coated with lead-free solder with a solar cell interconnector coated with lead-free solder. The solar cell string is characterized in that the lead-free solder applied as a coating on the solar cell and the solar cell interconnector is the lead-free solder including phosphorus. In the solar cell string, the lead-free solder applied as a coating on the solar cell and the interconnector for a solar cell preferably has the same composition.

According to an additional aspect of the present invention, a solar cell module has the solar cell string incorporated.

By improving the wettability of the lead-free solder applied as a coating on the electrode and reducing the thickness of the coating of the lead-free solder electrode in the solar cell of the present invention, detachment of the interconnector is suppressed, whereby the solar cell is improved in reliability. Accordingly, an interconnector coated with the lead-free solder, a solar cell string interconnecting the solar cell with the interconnector, and a solar cell module incorporating such a string are also improved in reliability.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic sectional view of a solar cell according to the present invention.

FIG. 2 is a diagram to describe a solar cell string of the present invention.

FIG. 3 is a diagram to describe fabrication steps of a solar cell.

FIG. 4 is a schematic sectional view of a conventional solar cell.

FIG. 5 is a diagram to describe a conventional solar cell string.

### DESCRIPTION OF THE PREFERRED EMBODIMENTS

A solar cell of the present invention includes an electrode coated with lead-free solder. The lead-free solder contains phosphorus (P). By virtue of the phosphorus in the lead-free solder, oxidation at the surface of solder is suppressed, eliminating incidental intrusion of oxide into the junction portion. Therefore, the uniform protection capability of the electrode and the like is improved. Also, metal glossiness is exhibited. The inclusion of phosphorus in lead-free solder is also advantageous in that the wettability of solder is improved, whereby the area of attachment with the electrode and the like is increased. Furthermore, the solder coating is reduced in thickness, so that expansion of the solder layer per se can be reduced. Thus, the load of stress on the electrode and the like can be alleviated, whereby the adherence between the solder and the electrode is improved.

The amount of phosphorus contained in lead-free solder is preferably 0.00001 to 0.5 mass %. If this amount is less than 0.0001 mass %, the aforementioned advantages due to the addition of phosphorus will not be exhibited. If the amount of phosphorus exceeds 0.5 mass %, the solder will become brittle. In view of the foregoing, the amount of phosphorus contained in the lead-free solder is preferably 0.0001 to 0.05 mass %, further preferably 0.0001 to 0.005 mass %.

Since phosphorus has favorable affinity for all of Sn, Ag and Bi, Sn—Bi—Ag based solder or Sn—Ag based solder can be employed. From the standpoint of reducing the dip temperature, Sn—Bi—Ag based solder is preferable. This is because Sn—Bi—Ag based solder or Sn—Ag based solder has a melting point lower than that of Sn solder. In the present invention, Sn—Bi—Ag based solder contains at least 0.1 mass % Ag. Also, Sn—Ag based solder contains at least 0.1 mass % Ag.

In the Sn—Bi—Ag based solder, the amount of Bi contained is preferably 3 to 89 mass %, further preferably 35 to 60 mass %. Such ranges of the amount of Bi are selected as set forth below. In order to conduct a solder dip step without any problems, it is desirable to carry out the dipping step at approximately 195° C., which is the current dip temperature. From the standpoint of property, reliability, and the like, dipping must be carried out at a temperature lower than 225° C. that is the upper limit in practical usage. A composition having a melting point of 225° C. at most corresponds to 5 to 88 mass % Bi when the amount of Ag contained is 0.1 mass %, and to 3-89 mass % Bi when the amount of Ag contained is 1.3 mass %. A composition having a melting point of 195° C. at most corresponds to 27 to 79 mass % Bi when the amount of Ag contained is 0.1 mass %, and to 35-60 mass % Bi when the amount of Ag contained is 1.3 mass % Ag. Thus, the amount of Bi contained is preferably 3-89 mass %, further preferably 35 to 60 mass % for Sn—Bi—Ag based solder.

In the case of Sn—Ag based solder, a composition having a melting point of 225° C. at most contains 3.5 to 4.5 mass % Ag. There is no composition of this Sn—Ag based solder that has a melting point of 195° C. and below. Thus, the amount of Ag contained is preferably 3.5 to 4.5 mass % for Sn—Ag based solder.

The electrode of the solar cell of the present invention can be formed by various methods such as silver paste firing, evaporation, sputtering, plating, or the like. From the standpoint of fabrication efficiency, formation through silver paste firing is preferable.

As to the silver paste used in producing the electrode of the solar cell, a silver paste material including, as the main component, powdery silver, powdery glass, an organic vehicle, and an organic solvent, as well as material including illidium chloride and phosphorus oxide can be employed.

The silver paste firing method includes the steps of applying silver paste by screen-printing to a thickness of 40 μm, for example, at a predetermined position at the back side of a p type silicon substrate, drying the silver paste for approximately 4 minutes at 150° C., printing a silver paste pattern in a manner similar to that of the above step at a predetermined position at the light receiving side of the p type silicon substrate, drying the silver paste, and then firing for two minutes in an oxidizing atmosphere at the temperature of 600° C., for example, whereby silver electrodes are formed at the front surface and the back surface.

The evaporation method includes the steps of forming a predetermined pattern using a resist at the surface of an anti-reflection film, etching away the anti-reflection film with HF, drying, depositing Ti, Pd and Ag sequentially to a thickness of 0.1 μm, 0.1 μm and 1 μm, respectively under the temperature of approximately 70° C., removing the resist, and then applying heat treatment in nitrogen under the temperature of 350° C., for example, whereby silver electrodes are formed. The sputtering process and evaporation process can be carried out through similar procedures.

The plating method includes the steps of forming a predetermined pattern using a resist on an anti-reflection film, etching away the anti-reflection film with HF, applying a pre-plating treatment, forming electroless-plated layers of Ni and Ag to a thickness of 0.5 μm and 2.5 μm, respectively, for example, removing the resist, and then applying heat treatment in nitrogen at 150° C., for example, whereby a silver electrode is formed.

Another solar cell of the present invention has a silver electrode coated with the above-described lead-free solder, wherein the average grain size of powdery glass included in the silver paste is 11 μm at most. In the present specification, “average grain size” is the average grain size obtained by light scattering diffractometry. If the average grain size of powdery glass exceeds 11 μm, the interconnector detachment rate will become higher under an environmental condition of great change in temperature and/or humidity. The uniform dispersibility of powdery glass becomes better as the average grain size of powdery glass becomes smaller, whereby the adherence in the silver paste and at the solar cell interface can be maintained. In view of the foregoing, the average grain size of powdery glass is preferably 8 μm at most, and more preferably 5 μm at most.

A solar cell according to another aspect of the present invention has a silver electrode coated with the above-described lead-free solder, wherein the amount of powdery glass included in the silver paste is 2.8 to 0.10.0 mass %. If the amount of powdery glass is less than 2.8 mass %, the interconnector detachment rate under the environmental condition of great change in temperature and/or humidity will become higher. If the amount of powdery glass exceeds 10%, homogenous paste cannot be obtained, rendering difficult the printing process of a solar cell. In view of the foregoing, the amount of powdery glass included in silver paste is preferably 2.8 to 7.0 mass %, further preferably 3.0 to 7.0 mass %, and most preferably 3.0 to 4.0 mass %.

A solar cell according to a further aspect of the present invention has a silver electrode coated with the above-described lead-free solder, wherein the average thickness of the silver electrode is preferably at least 15 μm. If the average thickness of the silver electrode after firing the silver paste is less than 15 μm, the strain stress imposed on the adhering interface between the n type diffusion layer or p type diffusion substrate and the silver electrode of the solar cell, generated by the difference in the coefficient of thermal expansion between the silicon substance of the solar cell and the substance of the silver electrode to which an interconnector is attached, can no longer be absorbed when the temperature and/or humidity changes greatly. This will lead to a higher interconnector detachment rate under the environmental condition of great change in temperature and/or humidity. In view of the foregoing, the film thickness of the silver electrode after the silver paste firing step is preferably at least 20 μm.

In the fabrication method of a solar cell of the present invention including the steps of printing silver paste at a partial region at a light receiving side of an anti-reflection film and at a partial region at a back side of a p type silicon substrate, firing the silver paste to form a silver electrode, and coating the silver electrode with lead-free solder including phosphorus, powdery glass sifted through a sieve in advance to reduce the average grain size of powdery glass contained in the silver paste is preferably employed. In addition to reducing the average grain size of powdery glass, the sifting process through a sieve is advantageous in that a particle size distribution containing more powdery glass of smaller grain size can be achieved by selectively removing powdery glass of large grain size. This contributes to maintaining adherence between silver electrodes 5, 6 and n type diffusion layer 2 or p type silicon substrate 1. In view of the foregoing, glass particles of large grain size can be removed sufficiently by using a sieve having an opening diameter of 73 μm at most. From the above-described standpoint, a sieve is employed having an opening diameter of preferably 50 μm at most, and further preferably 37 μm at most.

According to another embodiment of a fabrication method of a solar cell of the present invention including the steps of printing silver paste at a partial region at a light receiving side of an anti-reflection film and at a partial region at a back side of a p type silicon substrate, firing the silver paste to form a silver electrode, and coating the silver electrode with lead-free solder including phosphorus, the step of applying silver paste at least two times in the silver paste screen-printing process is preferably employed to increase the thickness of the silver electrode after firing the silver paste.

According to still another embodiment of a fabrication method of a solar cell of the present invention including the steps of printing silver paste at a partial region at a light receiving side of an anti-reflection film and at a partial region at a back side of a p type silicon substrate, firing the silver paste to form a silver electrode, and coating the silver electrode with lead-free solder including phosphorus, the step of printing silver paste using a mask having a thickness of three times the wire diameter is preferably employed in a silver paste screen-printing step in order to increase the thickness of the silver electrode after firing the silver paste. In the present specification, a mask having a thickness of three times the wire diameter is a mesh woven mask composed of longitudinal wire (warp) and transverse wire (weft), wherein the thickness of the screen fabric is set to be three times the wire diameter by increasing the tension on one of the longitudinal wire and transverse wire. The mask is used to apply a thick paste in the printing process. For example, a mesh woven mask of stainless steel wire (produced by Nakanuma Art Screen Co. Ltd.) can be used.

As to a flux used in producing an electrode of a solar cell, a flux material composed of only a polyalkylglycol-type resin and a solvent, absent of an activator, can be used. Namely, a flux containing a resin, a solvent, and a resin stabilizer can be used. The silver electrode is washed in a flux containing a resin, a solvent, and a resin stabilizer. Then, the silver electrode is coated with lead-free solder.

An interconnector for a solar cell of the present invention is coated with the above-described lead-free solder. In an interconnector, a copper (Cu) core line is generally used for the core line coated with lead-free solder. Phosphorus (P) has affinity for copper. By coating the core line with lead-free solder containing a small amount of phosphorus, the adherence with the core line is improved.

The solar cell string of the present invention is not particularly limited as long as the string interconnects the solar cell having an electrode coated with the above-described lead-free solder with an interconnector having a core line coated with the above-described lead free solder. The lead free solder applied as a coating on the electrode of the solar cell has a composition preferably identical to the composition of the lead-free solder applied as a coating on the core line of the interconnector. The same composition is advantageous in that soldering of higher reliability can be achieved more stably due to the matching melting temperature and improved compatibility.

The solar cell string of the present invention can be fabricated as set forth below. Referring to FIG. 2, an interconnector 12 coated with lead-free solder and cut to a predetermined length is brought into contact with a main electrode 11 coated with lead-free solder at the light receiving side of the solar cell. The solar cell and the interconnector are together exposed to a blow of hot air at approximately 400° C., whereby respective solder is melted, and then cooled to be solidified. Accordingly, the interconnector and the solar cell are integrated with each other. Then, the solar cell is inverted or the like such that a similar process can be carried out on the back surface electrode of the solar cell. Thus, a solar cell string of the present invention can be fabricated.

A solar cell module of the present invention incorporates the above-described string. By incorporating the above-described string, a module of high reliability, exhibiting high adherence between the interconnector and the solar cell can be produced. The module of the present invention is not restricted to any particular configuration as long as the above-described string is incorporated. For example, a super straight scheme is preferably employed, wherein the string is enclosed by a transparent filler and a back surface coat with a transparent substrate such as a glass plate at the light receiving side of the solar cell. As to the transparent filler, PVB (polyvinyl butyrol) exhibiting low light transmittance, EVA (ethylene vinyl acetate) superior in moisture resistance, and the like may be employed.

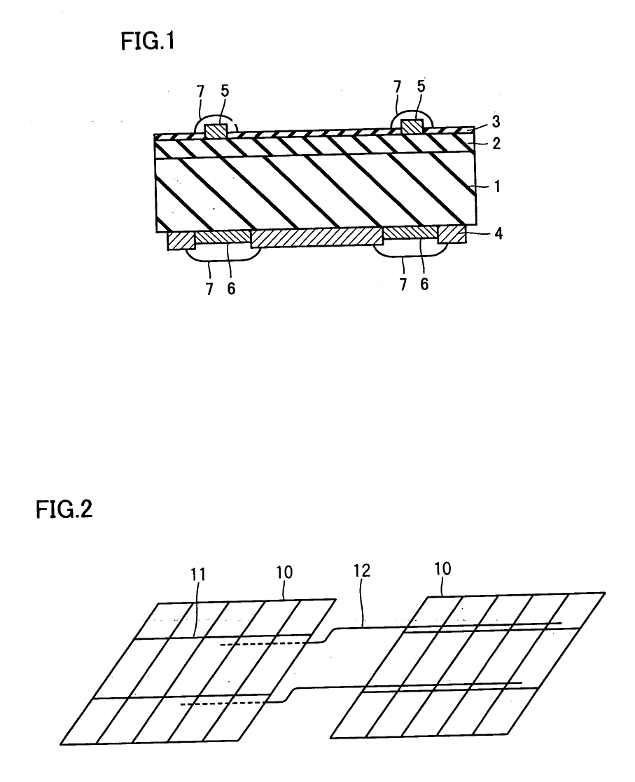

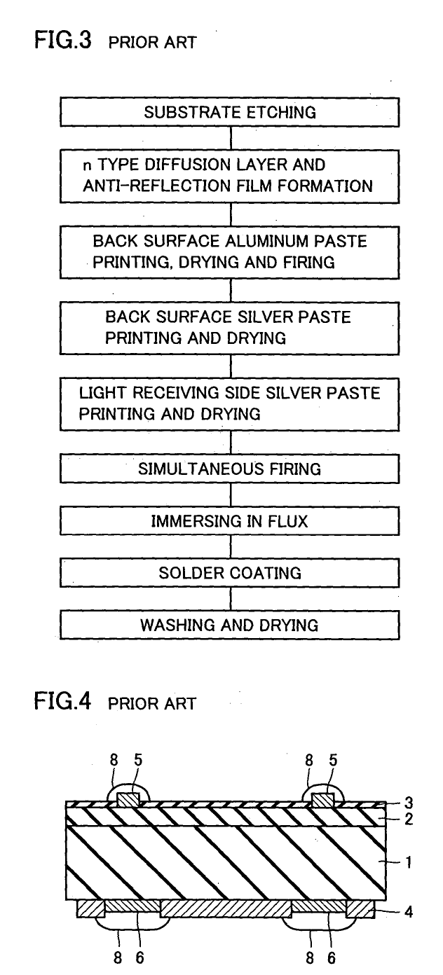

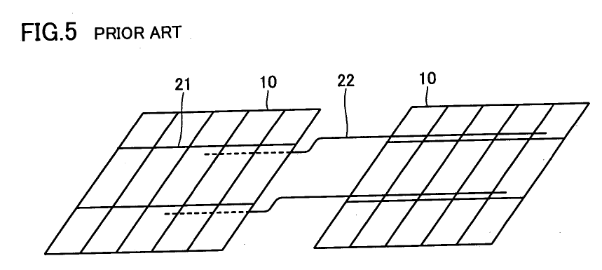

Examples of the present invention will be described with reference to the schematic sectional view of a solar cell of the present invention shown in FIG. 1. Referring to FIG. 1, on a texture-etched p type silicon substrate 1 having a thickness of 330 μm and an area of 125 mm by 125 mm, an n type diffusion layer 2 having a surface resistance of 50 Ω/□ was formed by thermal diffusion of phosphorus (P) at 900° C. Then, a silicon nitride film of 60 nm was formed thereon by plasma CVD (Chemical Vapor Deposition) as an anti-reflection film 3. Commercially available aluminum paste was applied by screen-printing on a major part of the back surface (excluding the silver electrode formation region), dried at approximately 150° C., and then fired in air at 700° C. to form back surface aluminum electrode 4.

Also, a silver paste firing step was conducted on p type silicon substrate 1 having n type diffusion layer 2 and anti-reflection film 3 at one side surface (light receiving side) and back surface electrode 4 at a major part of the other side surface (back side) to form silver electrodes 5 and 6.

The electrode formation step through silver paste firing was carried out in accordance with the following procedure. Silver paste with the basic composition of those shown in Table 1 set forth below was applied by screen-printing to a predetermined thickness at a predetermined region (the region where back surface aluminum electrode 4 is not formed) at the back surface of p type silicon substrate 1. This silver paste was dried for approximately 4 minutes at 150° C. Then, a pattern of silver paste was printed at the light receiving side. The silver paste was dried, and then fired for two minutes in an oxidizing atmosphere under the temperature of 600° C., whereby silver electrodes 5 and 6 were formed at the front side and the back side.

TABLE 1

| Components | Rate (mass %) |
|---|---|
| Powdery silver | 79.41 |
| Powdery glass | 2.00 |
| Organic vehicle | 7.54 |
| Phosphorous pentoxide | 0.10 |
| Organic solvent | 10.945 |
| Illidium chloride | 0.005 |

The solar cell with the silver electrode formed was immersed in a flux of the composition shown in Table 2 set forth below. Then, the solar cell was dried by hot air, and immersed in Sn—Bi—Ag based solder of the composition shown in Table 3 set forth below. Specifically, a predetermined amount of SnP alloy was dissolved into solder of a composition of mainly Sn—40Bi—1.25Ag. The solar cell was immersed in a solder bath of the composition of the Sn—40Bi—1.25Ag—0.001P, whereby lead-free solder layer 7 was formed. To improve the wettability, a small amount of antimony, gallium, and the like in addition to phosphorus can be included in the solder. Then, rinsing was conducted in pure water and hot pure water for a total of five minutes. The solar cell was dried to result in a completed solar cell. Although Table 3 shows Sn—Bi—Ag based solder and Sn—Ag based solder as the lead-free solder, either thereof can be used to cover the electrode. The average thickness and surface glossiness of solder depending on the varied amount of phosphorus in the lead-free solder are shown in Table 4 set forth afterwards.

TABLE 2

| Component | Rate (mass %) |
|---|---|
| Polyalkylglycol-type resin | 49.9 |
| Alcohol | 49.9 |
| Amine-type stabilizer | 0.2 |

TABLE 3

| Lead-free solder | Dip temperature (° C.) |
|---|---|
| Sn—Bi—Ag based | 193 |
| Sn—Ag based | 222 |

Connection of the solar cell described above with an interconnector coated with lead-free solder having the above-identified composition will be described hereinafter. An interconnector cut to a desired length was brought into contact with the silver electrode coated with lead-free solder of the solar cell. The interconnector and the solar cell were together subjected to a blow of hot air at approximately 400° C., whereby respective solder were melted and then cooled to be solidified. Thus, the interconnector and the solar cell were integrated with each other.

To evaluate the reliability of adherence between the solar cell and interconnector, a test piece having the silver electrode of such a solar cell connected to an interconnector was subjected to a temperature-humidity cycle test A-2 of JIS (Japanese Industrial Standard) C 8917 as an environmental condition of great change in temperature and/or humidity. The interconnector detachment rate was measured after the A-2 test was conducted for 10 cycles. JIS C 8917 corresponds to an environment testing method and endurance testing method for a solar cell module. In the present embodiment, a test piece having an interconnector connected to the silver electrode of a solar cell was employed.

“Interconnector detachment rate (%)” is the rate of the test points corresponding to detachment of the interconnector from the solar cell out of the test points of conducting the aforementioned temperature-humidity cycle test, expressed in percentage. Measurement was effected on five test pieces, ten points for one test piece (total of 50 points), for every one test.

<Effect of Amount of Phosphorus in Lead-Free Solder>

The relationship of the amount of phosphorus in the lead-free solder, the solder average thickness, the solder surface glossiness, and the interconnector detachment rate after the temperature-humidity cycle test is shown in Table 4 set forth below for Examples 1-3 of the present invention and Comparative Example 1. Evaluation of the solder surface glossiness was conducted by visual inspection. Those with glossiness are denoted by ◯ and those without glossiness are denoted by X. In the examples of Table 4, the amount of powdery glass was 2.0 mass % as shown in Table 1 as to the composition of the silver paste. The grain size of powdery glass was 11 m and the average thickness of the silver electrode was 10 μm.

TABLE 4

| | | | | Interconnector |
|---|---|---|---|---|
| | | Solder | | Detachment Rate |
| | P Amount | Average | Solder | After Temperature- |
| | in Solder | Thickness | Surface | Humidity Cycle Test |
| | (mass %) | (μm) | Glossiness | (%) |
| Comparative | 0 | 19 | X | 50 |
| Example 1 | | | | |
| Example 1 | 0.001 | 15 | ◯ | 2 |
| Example 2 | 0.003 | 15 | ◯ | 2 |
| Example 3 | 0.005 | 16 | ◯ | 2 |

It is appreciated from Table 4 that inclusion of phosphorus in the lead-free solder is advantageous in that the solder average film thickness is reduced and glossiness is exhibited at the solder surface. Also, the interconnector detachment rate can be reduced significantly, whereby the reliability of the solar cell is improved. A similar test was conducted with the coating solder of the interconnector altered to Sn—Ag—Cu based lead-free solder. No significant difference was found.

<Effect of Average Grain Size of Powdery Glass in Silver Paste>

The relationship between the average grain size of powdery glass included in the silver paste and the interconnector detachment rate after the temperature-humidity cycle test is shown in Table 5 set forth below for Examples 1, 4 and 5 of the present invention. In the examples of Table 5, the amount of phosphorous contained in the lead-free solder was 0.001 mass %. Also, the amount of powdery glass contained in the silver paste composition was 2.0 mass % as shown in Table 1, and the average thickness of the silver electrode was 10 μm.

TABLE 5

| | Average Grain Size | Interconnector |
|---|---|---|
| | of Powdery Glass in | Detachment Rate After |
| | Silver Paste | Temperature-Humidity |
| | (μm) | Cycle Test (%) |
| Example 4 | 20 | 10 |
| Example 1 | 11 | 2 |
| Example 5 | 5 | 0 |

As shown in Table 5, the interconnector detachment rate was further improved by setting the average grain size of powdery glass to 11 μm from 20 μm. No interconnector detachment was detected when the average grain size of powdery glass was set to 5 μm. It is therefore appreciated that the interconnector detachment rate can be further lowered by reducing the average grain size of powdery glass included in the silver paste. Accordingly, the reliability of a solar cell can be improved.

<Effect of Amount of Powdery Glass in Silver Paste>

The relationship between the amount of powdery glass (mass %) included in the silver paste and the interconnector detachment rate after the temperature-humidity cycle test is shown in Table 6 set forth below for Examples 1, 6, 7, and 8. The mass ratio of the composition of silver paste in the examples shown in Table 6 was similar to that shown in Table 1 with the exception of powdery glass. The examples were prepared with the amount of powdery glass respectively altered to 2.0 mass %, 2.8 mass %, 3.0 mass % and 4.0 mass %. In all the examples of Table 6, the amount of phosphorous contained in the lead-free solder was 0.001 mass %. The average grain size of powdery glass in the silver paste was 11 μm, and the average thickness of the silver electrode was 10 μm.

TABLE 6

| | | Interconnector |
|---|---|---|
| | Amount of Powdery | Detachment Rate After |
| | Glass in Silver | Temperature-Humidity |
| | Paste (mass %) | Cycle Test (%) |
| Example 1 | 2 | 2 |
| Example 6 | 2.8 | 0 |
| Example 7 | 3 | 0 |
| Example 8 | 4 | 0 |

As shown in Table 6, no detachment of the interconnector was detected by setting the amount of powdery glass to at least 2.8 mass %. The interconnector detachment rate can be further lowered by increasing the amount of powdery glass in the silver paste. Accordingly, the reliability of the solar cell can be improved.

<Effect of Average Thickness of Silver Electrode>

The relationship between the average thickness of a silver electrode and the interconnector detachment rate after the temperature-humidity cycle test is shown in Table 7 set forth below for Examples 1, 9 and 10. In all the examples of Table 7, the amount of phosphorous contained in the lead-free solder was 0.001 mass %. The amount of powdery glass contained in the silver paste composition was 2.0 mass % as shown in Table 1, and the average grain size of powdery glass was 11 μm.

TABLE 7

| | | Interconnector Detachment |
|---|---|---|
| | Average Thickness of | Rate After Temperature- |
| | Silver Electrode (μm) | Humidity Cycle Test (%) |
| Example 1 | 10 | 2 |
| Example 9 | 15 | 0 |
| Example 10 | 20 | 0 |

As shown in Table 7, no detachment of the interconnector was detected by setting the average thickness of the silver electrode to 15 μm from 10 μm. It is therefore appreciated that the interconnector detachment rate can be further lowered by increasing the average thickness of the silver electrode. Thus, the reliability of a solar cell can be improved.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A solar cell having an electrode coated with lead-free solder, wherein phosphorus is included in said lead-free solder.

2. The solar cell according to claim 1, wherein an amount of phosphorus in said lead-free solder is 0.00001 to 0.5 mass %.

3. The solar cell according to claim 1, wherein said lead-free solder is Sn—Bi—Ag based solder.

4. The solar cell according to claim 1, wherein said electrode is a silver electrode formed by firing silver paste.

5. The solar cell according to claim 4, wherein an average grain size of powdery glass included in said silver paste is 11 μm at most.

6. The solar cell according to claim 4, wherein an amount of powdery glass included in said silver paste is 2.8 to 10.0 mass %.

7. The solar cell according to claim 4, wherein said silver paste has an average thickness of at least 15 μm.

8. A fabrication method of a solar cell comprising the steps of printing silver paste at a partial region at alight receiving side of an anti-reflection film and at a partial region at a back side of a p type silicon substrate, firing said silver paste to form a silver electrode, and coating said silver electrode with lead-free solder including phosphorus, wherein powdery glass sifted through a sieve having an opening diameter of 73 μm at most is used as said powdery glass included in said silver paste.

9. A fabrication method of a solar cell comprising the steps of printing silver paste at a partial region at a light receiving side of an anti-reflection film and at a partial region at a back side of a p type silicon substrate, firing said silver paste to form a silver electrode, and coating said silver electrode with lead-free solder including phosphorus, wherein the step of printing silver paste includes applying silver paste at least two times.

10. A fabrication method of a solar cell comprising the steps of printing silver paste at a partial region at a light receiving side of an anti-reflection film and at a partial region at a back side of a p type silicon substrate, firing said silver paste to form a silver paste electrode, and coating said silver paste electrode with lead-free solder including phosphorus, wherein the step of printing silver paste includes applying silver paste using a mask having a thickness of three times a wire diameter.

11. An interconnector for a solar cell, said interconnector coated with lead-free solder, said lead-free solder including phosphorous.

12. A solar cell string interconnecting a solar cell coated with lead-free solder with a solar cell interconnector coated with lead-free solder, wherein said lead-free solder applied as a coating on said solar cell and said interconnector includes phosphorous.

13. The solar cell string according to claim 12, wherein said lead-free solder applied as a coating on the solar cell and the solar cell interconnector has the same composition.

14. A solar cell module incorporated with a string interconnecting a solar cell coated with lead-free solder including phosphorous with a solar cell interconnector coated with lead-free solder including phosphorous.
